(19) United States
(12) Patent Application Publication
(10) Pub. No.: US 2022/0254989 A1
(43) Pub. Date: Aug. 11, 2022

(54) PIEZOELECTRIC POLYMERS WITH HIGH POLYDISPERSITY

(71) Applicant: Facebook Technologies, LLC, Menlo Park, CA (US)

(72) Inventors: Andrew John Ouderkirk, Kirkland, WA (US); Sheng Ye, Redmond, WA (US); Kenneth Alexander Diest, Kirkland, WA (US)

(21) Appl. No.: 17/554,719

(22) Filed: Dec. 17, 2021

Related U.S. Application Data
(60) Provisional application No. 63/146,046, filed on Feb. 5, 2021.

(51) Int. Cl. H01L 41/193; C08F 14/22; C08J 5/18; C08J 7/12; H01L 41/257; H01L 41/45

(52) U.S. Cl. CPC H01L 41/193; C08F 14/22; C08J 5/18; C08J 2327/16; H01L 41/257; H01L 41/45; C08J 7/123

(57) ABSTRACT

A piezoelectric polymer article may be characterized by a Young's modulus of 5 GPa or greater along at least one dimension thereof. The piezoelectric polymer article may include polyvinylidene fluoride, for example, and may have a polydispersity index of at least 2. A piezoelectric coefficient of the polymer article, which may be a thin film or fiber, may be at least 20 pC/N.

### CROSS-REFERENCE TO RELATED APPLICATION

This application claims the benefit of priority under 35 U.S.C. § 119(e) of U.S. Provisional Application No. 63/146,046, filed Feb. 5, 2021, the contents of which are incorporated herein by reference in their entirety.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a schematic view of a single-stage thin film orientation system for manufacturing anisotropic piezoelectric polymer thin films according to some embodiments.

FIG. 2 is a schematic view of a thin film orientation system for manufacturing anisotropic piezoelectric polymer thin films according to some embodiments.

FIG. 3 is a schematic view of a thin film orientation system for manufacturing anisotropic piezoelectric polymer thin films according to further embodiments.

FIG. 4 is an illustration of exemplary augmented-reality glasses that may be used in connection with embodiments of this disclosure.

FIG. 5 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Polymer materials may be incorporated into a variety of different optic and electro-optic systems, including active and passive optics and electroactive devices. Lightweight and conformable, one or more polymer layers may be incorporated into wearable devices such as smart glasses and are attractive candidates for emerging technologies including virtual reality/augmented reality devices where a comfortable, adjustable form factor is desired.

Virtual reality (VR) and augmented reality (AR) eyewear devices and headsets, for instance, may enable users to experience events, such as interactions with people in a computer-generated simulation of a three-dimensional world or viewing data superimposed on a real-world view. By way of example, superimposing information onto a field of view may be achieved through an optical head-mounted display (OHMD) or by using embedded wireless glasses with a transparent heads-up display (HUD) or augmented reality (AR) overlay. VR/AR eyewear devices and headsets may be used for a variety of purposes. Governments may use such devices for military training, medical professionals may use such devices to simulate surgery, and engineers may use such devices as design visualization aids.

These and other applications may leverage one or more characteristics of polymer materials, including the refractive index to manipulate light, thermal conductivity to manage heat, and mechanical strength and toughness to provide light-weight structural support. The degree of optical or mechanical anisotropy achievable through comparative thin film manufacturing processes is typically limited, however, and is often exchanged for competing thin film properties such as flatness, toughness and/or film strength. For example, highly anisotropic polymer thin films often exhibit low strength in one or more in-plane direction, which may challenge manufacturability and limit throughput.

According to some embodiments, oriented piezoelectric polymer thin films may be implemented as an actuatable lens substrate in an optical element such as a liquid lens. Uniaxially-oriented polyvinylidene fluoride (PVDF) thin films, for example, may be used to generate an advantageously anisotropic strain map across the field of view of a lens. However, low piezoelectric response, insufficient mechanical strength or toughness, and/or a lack of adequate optical quality may impede the implementation of PVDF thin films as an actuatable layer.

Notwithstanding recent developments, it would be advantageous to provide optical quality, mechanically robust, and mechanically and piezoelectrically anisotropic polymer thin films that may be incorporated into various optical systems including display systems for artificial reality applications. The instant disclosure is thus directed generally to high modulus, high strength, optical quality polymer thin films having a high and efficient piezoelectric response as well as their methods of manufacture, and more specifically to casting, stretching and annealing methods for forming mechanically stable PVDF-based polymer thin films and fibers having a high electromechanical efficiency. A higher modulus may allow greater forces to be generated in the polymer, which may enable thinner, lighter weight, and more efficient devices (e.g., for converting mechanical energy into electrical energy or vice versa).

The refractive index and piezoelectric response of a polymer thin film may be determined by its chemical composition, the chemical structure of the polymer repeat unit, its density and extent of crystallinity, as well as the alignment of the crystals and/or polymer chains. Among these factors, the crystal or polymer chain alignment may dominate. In crystalline or semi-crystalline polymer thin films and fibers, the piezoelectric response may be correlated to the degree or extent of crystal orientation, whereas the degree or extent of chain alignment may create comparable piezoelectric response in amorphous polymers.

An applied stress may be used to create a preferred alignment of crystals or polymer chains within a polymer thin film or fiber and induce a corresponding modification of the refractive index and piezoelectric response along different directions of the film or fiber. As disclosed further herein, during processing where a polymer thin film is stretched to induce a preferred alignment of crystals/polymer chains and an attendant modification of the refractive index and piezoelectric response, Applicants have shown that the choice of the initial polymer microstructure can decrease the propensity for polymer chain entanglement within the cast thin film. In particular embodiments, the polymer material may be characterized by a bimodal distribution of its molecular weight or a high polydispersity index.

In accordance with particular embodiments, Applicants have developed polymer thin film manufacturing methods for forming an optical quality and mechanically robust PVDF-based polymer thin film having a desired piezoelectric response. Whereas in PVDF and related polymers, the total extent of crystallization as well as the alignment of crystals may be limited due to polymer chain entanglement, a casting and stretching method using a polydisperse polymer feedstock may facilitate the disentanglement and alignment of polymer chains, which may lead to improvements in the optical quality and mechanical toughness of a polymer thin film as well as improvements in its piezoelectric efficiency and response.

PVDF-based polymer thin films may be formed using a crystallizable polymer. Example crystallizable polymers may include moieties such as vinylidene fluoride (VDF), trifluoroethylene (TrFE), chlorotrifluoroethylene (CTFE), hexafluoropropene (HFP), and vinyl fluoride (VF). According to various embodiments, a polymer thin film may include one or more of the foregoing moieties, as well as mixtures and co-polymers thereof. According to some embodiments, one or more of the foregoing “PVDF-family” moieties may be combined with a low molecular weight additive to form a piezoelectric polymer thin film. As used herein, reference to a PVDF thin film includes reference to any PVDF-family member-containing polymer thin film unless the context clearly indicates otherwise.

The crystallizable polymer component of such a PVDF thin film may have a molecular weight (“high molecular weight”) of at least approximately 100,000 g/mol, e.g., at least approximately 100,000 g/mol, at least approximately 150,000 g/mol, at least approximately 200,000 g/mol, at least approximately 250,000 g/mol, at least approximately 300,000 g/mol, at least approximately 350,000 g/mol, at least approximately 400,000 g/mol, at least approximately 450,000 g/mol, or at least approximately 500,000 g/mol, including ranges between any of the foregoing values.

A “low molecular weight” polymer or additive may have a molecular weight of less than approximately 200,000 g/mol, e.g., less than approximately 200,000 g/mol, less than approximately 100,000 g/mol, less than approximately 50,000 g/mol, less than approximately 25,000 g/mol, less than approximately 10,000 g/mol, less than approximately 5000 g/mol, less than approximately 2000 g/mol, less than approximately 1000 g/mol, less than approximately 500 g/mol, less than approximately 200 g/mol, or less than approximately 100 g/mol, including ranges between any of the foregoing values.

Example low molecular weight additives may include oligomers and polymers of vinylidene fluoride (VDF), trifluoroethylene (TrFE), chlorotrifluoroethylene (CTFE), hexafluoropropene (HFP), and vinyl fluoride (VF), as well as homopolymers, co-polymers, tri-polymers, derivatives, and combinations thereof. Such additives may be readily soluble in, and provide refractive index matching with, the high molecular weight component. An example additive may have a refractive index measured at 652.9 nm of from approximately 1.38 to approximately 1.55.

The molecular weight of a low molecular weight additive may be less than the molecular weight of the high molecular weight crystallizable polymer. In some embodiments, the average molecular weight of the low molecular weight polymer (additive) may be approximately 50% of the average molecular weight of the high molecular weight polymer.

According to some embodiments, further example low molecular weight additives may include a lubricant. The addition of one or more lubricants may provide intermolecular interactions with PVDF-family member chains and a beneficially lower melt viscosity. Example lubricants may include metal soaps, hydrocarbon waxes, low molecular weight polyethylene, fluoropolymers, amide waxes, fatty acids, fatty alcohols, and esters.

Further example low molecular weight additives may include oligomers and polymers that may have polar interactions with PVDF-family member chains. Such oligomers and polymers may include ester, ether, hydroxyl, phosphate, fluorine, halogen, or nitrile groups. Particular examples include polymethylmethacrylate, polyethylene glycol, and polyvinyl acetate. PVDF polymer and PVDF oligomer-based additives, for example, may include a reactive group such as vinyl, acrylate, methacrylate, epoxy, isocyanate, hydroxyl, or amine, and the like. Such additives may be cured in situ, i.e., within a polymer thin film, by applying one or more of heat or light or by reaction with a suitable catalyst.

Still further example polar additives may include ionic liquids, such as 1-octadecyl-3-methylimidazolium bromide, 1-butyl-3-methylimidazolium[PF₆], 1-butyl-3-methylimidazolium[BF₄], 1-butyl-3-methylimidazolium[FeCl₄] or [1-butyl-3-methylimidazolium[Cl]. According to some embodiments, the amount of an ionic liquid may range from approximately 1 to 15 wt. % of the polymer thin film.

In some examples, the low molecular weight additive may include an inorganic additive. An inorganic additive may increase the piezoelectric performance of the polymer thin film. Example inorganic additives may include nanoparticles (e.g., ceramic nanoparticles such as PZT, BNT, or quartz; or metal or metal oxide nanoparticles), ferrite nanocomposites (e.g., Fe₂O₃—CoFe₂O₄), and hydrated salts or metal halides, such as LiCl, Al(NO₃)₃-9H₂O, BiCl₃, Ce or Y nitrate hexahydrate, or Mg chlorate hexahydrate. The amount of an inorganic additive may range from approximately 0.001 to 5 wt. % of the polymer thin film.

Generally, a low molecular weight additive may constitute up to approximately 90 wt. % of the polymer thin film, e.g., approximately 0.001 wt. %, approximately 0.002 wt. %, approximately 0.005 wt. %, approximately 0.01 wt. %, approximately 0.02 wt. %, approximately 0.05 wt. %, approximately 0.1 wt. %, approximately 0.2 wt. %, approximately 0.5 wt. %, approximately 1 wt. %, approximately 2 wt. %, approximately 5 wt. %, approximately 10 wt. %, approximately 20 wt. %, approximately 30 wt. %, approximately 40 wt. %, approximately 50 wt. %, approximately 60 wt. %, approximately 70 wt. %, approximately 80 wt. %, or approximately 90 wt. %, including ranges between any of the foregoing values.

In some embodiments, one or more additives may be used. According to particular examples, an original additive can be used during processing of a thin film (e.g., during casting, stretching, and/or poling). Thereafter, the original additive may be removed and replaced by a secondary additive. Micro and macro voids produced during solvent removal or stretching process can be filled by the secondary additive, for example. A secondary additive may be index matched to the crystalline polymer and may, for example, have a refractive index ranging from approximately 1.38 to approximately 1.55. A secondary additive can be added by soaking the thin film in a melting condition or in a solvent bath. A secondary additive may have a melting point of less than approximately 100° C.

In some embodiments, a piezoelectric polymer thin film may include an antioxidant. Example antioxidants include hindered phenols, phosphites, thiosynergists, hydroxylamines, and oligomer hindered amine light stabilizers (HALS).

In certain examples, the molecular weight distribution for the high and low molecular weight polymers may be independently chosen from mono-disperse, bimodal, or polydisperse. A polymer (e.g., a high molecular weight polymer) having a bimodal molecular weight distribution may be characterized by two molecular weight distribution maxima, one in a low(er) molecular weight region and one in a high(er) molecular weight region.

The polydispersity or heterogeneity index, which is a measure of the broadness of a molecular weight distribution of a polymer, may be used to characterize a polymer composition. The polydispersity index (PDI) may be calculated as the ratio of weight average molecular weight (M_{w}) to number average molecular weight (Mₙ) of a polymer sample, i.e., PDI=M_{w}/Mₙ. In accordance with certain embodiments, example high molecular weight polymers may have a polydispersity index of at least approximately 2, e.g., approximately 2, approximately 2.5, approximately 3, approximately 3.5, or approximately 4, including ranges between any of the foregoing values.

Thus, in some embodiments, the crystallizable polymer and the low molecular weight additive may be independently selected to include vinylidene fluoride (VDF), trifluoroethylene (TrFE), chloride trifluoride ethylene (CTFE), hexafluoropropene (HFP), vinyl fluoride (VF), as well as homopolymers, co-polymers, tri-polymers, derivatives, and combinations thereof. The high molecular weight component of the polymer thin film may have a molecular weight of at least 100,000 g/mol, whereas the low molecular weight additive may have a molecular weight of less than 200,000 g/mol and may constitute 0.1 wt. % to 90 wt. % of the polymer thin film.

According to one example, the crystallizable polymer may have a molecular weight of at least approximately 100,000 g/mol and the additive may have a molecular weight of less than approximately 25,000 g/mol. According to a further example, the crystallizable polymer may have a molecular weight of at least approximately 300,000 g/mol and the additive may have a molecular weight of less than approximately 200,000 g/mol. Use herein of the term “molecular weight” may, in some examples, refer to a weight average molecular weight.

A polymer thin film may be formed by casting from a polymer solution or melt. A polymer solution, for instance, may include one or more high molecular weight polymers, one or more low molecular weight additives, and one or more liquid solvents. As disclosed herein, the polymer solution or melt may include a mixture of (i) high molecular weight PVDF (and/or its copolymers) and (ii) low molecular weight PVDF (and/or its copolymers) or mixtures thereof with one or more low molecular weight additives, including miscible polymers, oligomers, and curable monomers.

Suitable liquid solvents may include a chemical compound or mixture of chemical compounds that can at least partially dissolve or substantially swell the polymer constituent(s). In some embodiments, a liquid solvent may have a vapor pressure of at least approximately 10 mTorr at 100° C.

The liquid solvent (i.e., “solvent”) may include a single solvent composition or a mixture of different solvents. In some embodiments, the solubility of the crystallizable polymer in the liquid solvent may be at least approximately 0.1 g/100 g (e.g., 1 g/100 g or 10 g/100 g) at a temperature of approximately 25° C. or more (e.g., 50° C., 75° C., 100° C., or 150° C., including ranges between any of the foregoing values). The choice of solvent may affect the maximum crystallinity and percent beta phase content of a PVDF-based polymer thin film, which may impact its piezoelectric response. In addition, the polarity of the solvent may impact the critical polymer concentration for polymer chains to entangle in solution.

Example solvents include, but are not limited to, dimethylformamide (DMF), cyclohexanone, dimethylacetamide (DMAc), diacetone alcohol, di-isobutyl ketone, tetramethyl urea, ethyl acetoacetate, dimethyl sulfoxide (DMSO), trimethyl phosphate, N-methyl-2-pyrrolidone (NMP), butyrolactone, isophorone, triethyl phosphate, carbitol acetate, propylene carbonate, glyceryl triacetate, dimethyl phthalate, acetone, tetrahydrofuran (THF), methyl ethyl ketone, methyl isobutyl ketone, glycol ethers, glycol ether esters, and N-butyl acetate.

According to some embodiments, a method of manufacturing a piezoelectric polymer article may include extruding a polymer solution or melt through an orifice to form a cast polymer article, and subsequently heating and stretching the cast polymer article. A casting method may provide control of one or more of the solvent, polymer concentration, and casting temperature, for example, and may facilitate decreased entanglement of polymer chains and allow the polymer thin film or fiber to achieve a higher stretch ratio during a subsequent deformation step.

A polymer composition having a bimodal molecular weight or high polydispersity index may be formed into a single layer using casting operations. Alternatively, a polymer composition having a bimodal molecular weight or high polydispersity index may be cast with other polymers or other non-polymer materials to form a multilayer thin film. The application of a uniaxial or biaxial stress to a cast single or multilayer thin film may be used to align polymer chains and/or re-orient crystals to induce mechanical and piezoelectric anisotropy therein.

A piezoelectric polymer thin film may be formed from a composition that includes a crystallizable polymer and a low molecular weight additive. In particular embodiments, a piezoelectric polymer thin film having a high electromechanical efficiency may be formed by casting. An example method may include forming a solution of a crystallizable polymer and a solvent, removing a portion of the solvent to form a cast polymer thin film, orienting, and then poling the thin film. The choice of solvent may facilitate chain disentanglement and accordingly polymer chain and dipole alignment, e.g., during orienting. During the casting step, the solution may include at least approximately 25 wt. % solvent, e.g., at least approximately 50 wt. %, at least approximately 70 wt. %, at least approximately 80 wt. %, at least approximately 90 wt. %, or more, including ranges between any of the foregoing values. The solution may be cast directly onto a surface and at least partially dried, or the solution may be heated and cooled to form a gel, which is cast onto a surface. Suitable surfaces may include a drum or a belt. During an orienting step, the cast polymer may include less than approximately 10 wt. % liquid solvent.

After casting, the PVDF film can be oriented either uniaxially or biaxially as a single layer or multilayer to form a piezoelectrically anisotropic film. An anisotropic polymer thin film may be formed using a thin film orientation system configured to heat and stretch a polymer thin film in at least one in-plane direction in one or more distinct regions thereof. In some embodiments, a thin film orientation system may be configured to stretch a polymer thin film, i.e., a crystallizable polymer thin film, along only one in-plane direction. For instance, a thin film orientation system may be configured to apply an in-plane stress to a polymer thin film along the x-direction while allowing the thin film to relax along an orthogonal in-plane direction (i.e., along the y-direction). The relaxation of a polymer thin film may, in certain examples, accompany the absence of an applied stress along a relaxation direction.

According to some embodiments, within an example system, a polymer thin film may be heated and stretched transversely to a direction of film travel through the system. In such embodiments, a polymer thin film may be held along opposing edges by plural movable clips slidably disposed along a diverging track system such that the polymer thin film is stretched in a transverse direction (TD) as it moves along a machine direction (MD) through heating and deformation zones of the thin film orientation system. In some embodiments, the stretching rate in the transverse direction and the relaxation rate in the machine direction may be independently and locally controlled. In certain embodiments, large scale production may be enabled, for example, using a roll-to-roll manufacturing platform.

In certain aspects, the tensile stress may be applied uniformly or non-uniformly along a lengthwise or widthwise dimension of the polymer thin film. Heating of the polymer thin film may accompany the application of the tensile stress. For instance, a semi-crystalline polymer thin film may be heated to a temperature greater than room temperature (^{˜}23° C.) to facilitate deformation of the thin film and the formation and realignment of crystals and/or polymer chains therein.

The temperature of the polymer thin film may be maintained at a desired value or within a desired range before, during and/or after the act of stretching, i.e., within a pre-heating zone or a deformation zone downstream of the pre-heating zone, in order to improve the deformability of the polymer thin film relative to an un-heated polymer thin film. The temperature of the polymer thin film within a deformation zone may be less than, equal to, or greater than the temperature of the polymer thin film within a pre-heating zone.

In some embodiments, the polymer thin film may be heated to a constant temperature throughout the act of stretching. In some embodiments, different regions of the polymer thin film may be heated to different temperatures, i.e., during and/or subsequent to the application of a tensile stress. In certain embodiments, the strain realized in response to the applied tensile stress may be at least approximately 20%, e.g., approximately 20%, approximately 50%, approximately 100%, approximately 200%, approximately 400%, approximately 500%, approximately 1000%, approximately 2000%, approximately 3000%, or approximately 4000% or more, including ranges between any of the foregoing values.

In various examples, a modulus of elasticity of the stretched polymer article along a stretch direction thereof may be proportional to the stretch ratio. Higher stretch ratios may effectively unfold relatively elastic lamellar polymer crystals and increase the extent of crystal alignment within the resulting piezoelectric polymer article.

In some embodiments, the crystalline content within the polymer thin film may increase during the act of stretching. In some embodiments, stretching may alter the orientation of crystals within a polymer thin film without substantially changing the crystalline content.

The application of a uniaxial or biaxial stress to a single or multilayer thin film may be used to align polymer chains and/or orient crystals to induce optical and mechanical anisotropy. Such thin films may be used to fabricate anisotropic piezoelectric substrates, birefringent substrates, high Poisson's ratio thin films, reflective polarizers, birefringent mirrors, and the like, and may be incorporated into AR/VR combiners or used to provide display brightness enhancement.

A piezoelectric polymer thin film may be formed by applying a stress to a cast polymer thin film or fiber. In some embodiments, a polymer thin film having a bimodal molecular weight distribution, or a high polydispersity index, may be stretched to a larger stretch ratio than a comparative polymer thin film (e.g., lacking a low molecular weight additive). In some examples, a stretch ratio may be greater than 4, e.g., 5, 10, 20, 40, or more. The act of stretching may include a single stretching step or plural (i.e., successive) stretching steps where one or more of a stretching temperature and a strain rate may be independently controlled.

An example method of forming a piezoelectric polymer thin film may include uniaxially orienting a cast polymer thin film with a stretch ratio of at least approximately 400% (e.g., 400%, 500%, 600%, 700%, 800%, 900%, 1000%, or 2000% or more, including ranges between any of the foregoing values). A further example method of forming a piezoelectric polymer thin film may include biaxially orienting a cast polymer thin film with independent stretch ratios along each in-plane direction of at least approximately 400% (e.g., 400%, 500%, 600%, 700%, 800%, 900%, 1000%, or 2000% or more, including ranges between any of the foregoing values).

Without wishing to be bound by theory, one or more low molecular weight additives may interact with high molecular weight polymers throughout casting and stretch processes to facilitate less chain entanglement and better chain alignment and, in some examples, create a higher crystalline content within the polymer thin film. That is, a composition having a bimodal molecular weight distribution or high polydispersity index may be cast to form a thin film, which may be stretched to induce mechanical and piezoelectric anisotropy through crystal and/or chain realignment. Stretching may include the application of a uniaxial stress or a biaxial stress. In some embodiments, the application of an in-plane biaxial stress may be performed simultaneously or sequentially. In some embodiments, the low molecular weight additive may beneficially decrease the draw temperature of the polymer composition during casting. In some embodiments, a polymer thin film may be stretched by calendaring or extruding.

In example methods, the polymer thin film may be heated during stretching to a temperature of from approximately 60° C. to approximately 170° C. and stretched at a strain rate of from approximately 0.1%/sec to approximately 300%/sec. Moreover, one or both of the temperature and the strain rate may be held constant or varied during the act of stretching. For instance, in an illustrative but non-limiting example, a polymer thin film may be stretched at a first temperature and a first strain rate (e.g., 130° C. and 50%/sec) to achieve a first stretch ratio. Subsequently, the temperature of the polymer thin film may be increased, and the strain rate may be decreased to a second temperature and a second strain rate (e.g., 165° C. and 5%/sec) to achieve a second stretch ratio.

Following deformation of the polymer thin film, the heating may be maintained for a predetermined amount of time, followed by cooling of the polymer thin film. The act of cooling may include allowing the polymer thin film to cool naturally, at a set cooling rate, or by quenching, such as by purging with a low temperature gas, which may thermally stabilize the polymer thin film.

Stretching a PVDF-family film may form both alpha and beta phase crystals, although only aligned beta phase crystals contribute to a piezoelectric response. During and/or after a stretching process, an electric field may be applied to the polymer thin film. The application of an electric field (i.e., poling) may induce the formation and alignment of beta phase crystals within the film. Whereas a lower electric field (<50 V/micrometer) can be applied to align beta phase crystals, a higher electric field (≥50 V/micrometer) can be applied to both induce a phase transformation from the alpha phase to the beta phase and encourage alignment of the beta phase crystals.

In some embodiments, following stretching, the polymer thin film may be annealed. Annealing may be performed at a fixed or variable stretch ratio and/or a fixed or variable applied stress. An example annealing temperature may be greater than approximately 80° C., e.g., 100° C., 130° C., or 170° C., including ranges between any of the foregoing values. Without wishing to be bound by theory, annealing may stabilize the orientation of polymer chains and decrease the propensity for shrinkage of the polymer thin film.

Following deformation, the crystals or chains may be at least partially aligned with the direction of the applied tensile stress. As such, a polymer thin film may exhibit a high degree of birefringence, a high degree of optical clarity, bulk haze of less than approximately 10%, a high piezoelectric coefficient, e.g., d₃₁ greater than 5 pC/N and/or a high electromechanical coupling factor, e.g., k₃₁ greater than 0.1.

Such a stretched polymer thin film may exhibit higher crystallinity and a higher modulus. By way of example, an oriented polymer thin film having a bimodal molecular weight distribution may have an in-plane modulus greater than approximately 2 GPa, e.g., 3, 5, 10, 12, or 15 GPa, including ranges between any of the foregoing values, and a piezoelectric coefficient (d₃₁) greater than 5 pC/N. High piezoelectric performance may be associated with the creation and alignment of beta phase crystals in PVDF-family polymers.

Further to the foregoing, an electromechanical coupling factor kᵢⱼ may indicate the effectiveness with which a piezoelectric material can convert electrical energy into mechanical energy, or vice versa. For a polymer thin film, the electromechanical coupling factor k₃₁ may be expressed as

$${k}_{31} = \frac{d 31}{\sqrt{e 33 * s 31}} ,$$

where d₃₁ is the piezoelectric strain coefficient, e₃₃ is the dielectric permittivity in the thickness direction, and s₃₁ is the compliance in the machine direction. Higher values of k₃₁ may be achieved by disentangling polymer chains prior to stretching and promoting dipole moment alignment within a crystalline phase. In some embodiments, a polymer thin film may be characterized by an electromechanical coupling factor k₃₁ of at least approximately 0.1, e.g., 0.1, 0.2, 0.3, or more, including ranges between any of the foregoing values.

In accordance with various embodiments, anisotropic polymer thin films may include fibrous, amorphous, partially crystalline, or wholly crystalline materials. Such materials may also be mechanically anisotropic, where one or more characteristics selected from compressive strength, tensile strength, shear strength, yield strength, stiffness, hardness, toughness, ductility, machinability, thermal expansion, piezoelectric response, and creep behavior may be directionally dependent.

Stretching and the associated chain/crystal alignment may be accompanied by poling to form a polymer thin film or fiber having a high electromechanical efficiency. The acts of stretching and poling may be performed sequentially, simultaneously, or in an overlapping manner. An electric field may be applied to the polymer article during and/or following the act of stretching. By way of example, during and/or after stretching, a polymer thin film may be poled by applying a voltage across its thickness dimension of at least approximately 50 V/micrometer, e.g., 50, 75, 100, or 150 V/micrometer, including ranges between any of the foregoing values.

According to further embodiments, a polymer article may be exposed to actinic radiation. A polymer thin film, for example, may be exposed to actinic radiation prior to, during, and/or following poling. Moreover, actinic radiation exposure may occur prior to, during, and/or after the act of stretching. Example of suitable actinic radiation include gamma, beta, and alpha radiation, electron beams, UV light, and x-rays.

According to some examples, a calendaring process may be used to orient polymer chains at room temperature or at elevated temperature. Calendaring may include feeding a dried or substantially dried polymer material (i.e., resin) between rotating drums that compress and consolidate the resin to form a film. The film may then be stretched.

According to further examples, a solid state extrusion process may be used to orient the polymer chains. In an example process, a dried or substantially dried polymer material may be hot pressed to form a desired shape that is fed through a solid state extrusion system (i.e., extruder) at a suitable extrusion temperature. A solid state extruder may include a bifurcated nozzle, for example. The temperature for hot pressing and the extrusion temperature may each be less than approximately 190° C. That is, the hot pressing temperature and the extrusion temperature may be independently selected from 180° C., 170° C., 160° C., 150° C., 130° C., 110° C., 90° C., or 80° C., including ranges between any of the foregoing values. According to particular embodiments, the extruded polymer material may be stretched further, e.g., using a post-extrusion, uniaxial stretch process. The liquid solvent may be partially or fully removed before, during, or after stretching and orienting.

The crystalline content of a piezoelectric polymer thin film may include crystals of poly(vinylidene fluoride), poly(trifluoroethylene), poly(chlorotrifluoroethylene), poly(hexafluoropropene), and/or poly(vinyl fluoride), for example, although further crystalline polymer materials are contemplated, where a crystalline phase in a “crystalline” or “semi-crystalline” polymer thin film may, in some examples, constitute at least approximately 1% of the polymer thin film. For instance, the crystalline content (e.g., beta phase content) of a polymer thin film may be at least approximately 1%, e.g., 1, 2, 4, 10, 20, 40, 60, or 80%, including ranges between any of the foregoing values.

A piezoelectric polymer article such as a polymer thin film may, in some embodiments, have a Young's modulus along at least one direction (e.g., length or width) of at least approximately 5 GPa (e.g., 5 GPa, 10 GPa, 20 GPa, or 30 GPa or more, including ranges between any of the foregoing values). In some embodiments, a piezoelectric polymer article may have a Young's modulus along each of a pair of in-plane directions (e.g., length and width) that may independently be at least approximately 5 GPa (e.g., 5 GPa, 10 GPa, 20 GPa, or 30 GPa or more, including ranges between any of the foregoing values). A piezoelectric polymer article may be characterized by a piezoelectric coefficient along at least one direction of at least approximately 20 pC/N (e.g., 20 pC/N, 30 pC/N, or 40 pC/N or more, including ranges between any of the foregoing values).

The presently disclosed anisotropic PVDF-based polymer thin films may be characterized as optical quality polymer thin films and may form, or be incorporated into, an optical element as an actuatable layer. Optical elements may be used in various display devices, such as virtual reality (VR) and augmented reality (AR) glasses and headsets. The efficiency of these and other optical elements may depend on the degree of optical clarity and/or piezoelectric response.

According to various embodiments, an “optical quality thin film” or an “optical quality polymer thin film” may, in some examples, be characterized by a transmissivity within the visible light spectrum of at least approximately 20%, e.g., 20, 30, 40, 50, 60, 70, 80, 90 or 95%, including ranges between any of the foregoing values, and less than approximately 10% bulk haze, e.g., 0.1, 0.2, 0.5, 1, 2, 4, 6, or 8% bulk haze, including ranges between any of the foregoing values.

In further embodiments, an optical quality PVDF-based polymer thin film may be incorporated into a multilayer structure, such as the “A” layer in an ABAB multilayer. Further multilayer architectures may include AB, ABA, ABAB, or ABC configurations. Each B layer (and each C layer, if provided) may include a further polymer composition, such as polyethylene. According to some embodiments, the B (and C) layer(s) may be electrically conductive and may include, for example, indium tin oxide (ITO) or poly(3,4-ethylenedioxythiophene).

In a single layer or multilayer architecture, each PVDF-family layer may have a thickness ranging from approximately 100 nm to approximately 5 mm, e.g., 100, 200, 500, 1000, 2000, 5000, 10000, 20000, 50000, 100000, 200000, 500000, 1000000, 2000000, or 5000000 nm, including ranges between any of the foregoing values. A multilayer stack may include two or more such layers. In some embodiments, a density of a PVDF layer or thin film may range from approximately 1.7 g/cm³ to approximately 1.9 g/cm³, e.g., 1.7, 1.75, 1.8, 1.85, or 1.9 g/cm³, including ranges between any of the foregoing values.

According to some embodiments, the areal dimensions (i.e., length and width) of an anisotropic PVDF-family polymer thin film may independently range from approximately 5 cm to approximately 50 cm or more, e.g., 5, 10, 20, 30, 40, or 50 cm or more, including ranges between any of the foregoing values. Example piezoelectric polymer thin films may have areal dimensions of approximately 5 cm×5 cm, 10 cm×10 cm, 20 cm×20 cm, 50 cm×50 cm, 5 cm×10 cm, 10 cm×20 cm, 10 cm×50 cm, etc.

As used herein, the terms “polymer thin film” and “polymer layer” may be used interchangeably. Furthermore, reference to a “polymer thin film” or a “polymer layer” may include reference to a “multilayer polymer thin film” unless the context clearly indicates otherwise.

Aspects of the present disclosure thus relate to the formation of a single layer or multilayer polymer thin film having a high piezoelectric response and improved mechanical properties, including strength and toughness. The improved mechanical properties may also include improved dimensional stability and improved compliance in conforming to a surface having compound curvature, such as a lens.

Features from any of the embodiments described herein may be used in combination with one another in accordance with the general principles described herein. These and other embodiments, features, and advantages will be more fully understood upon reading the following detailed description in conjunction with the accompanying drawings and claims.

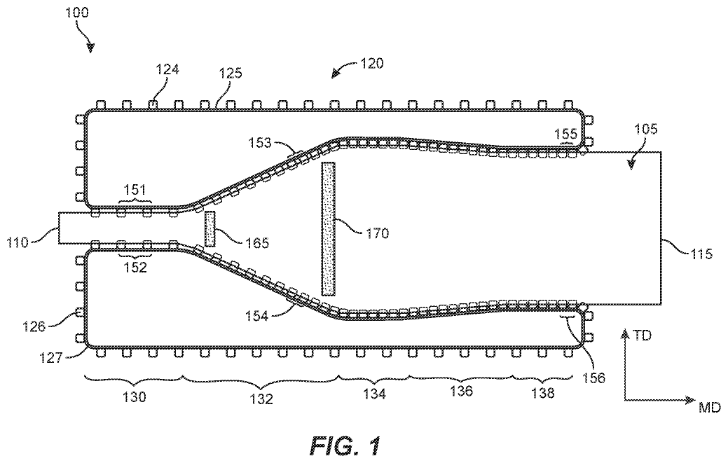

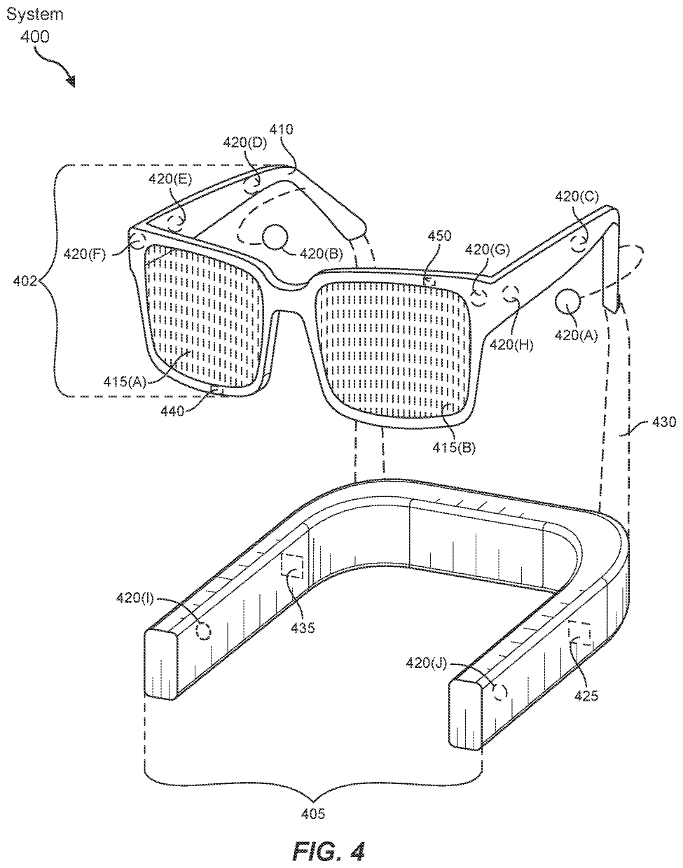

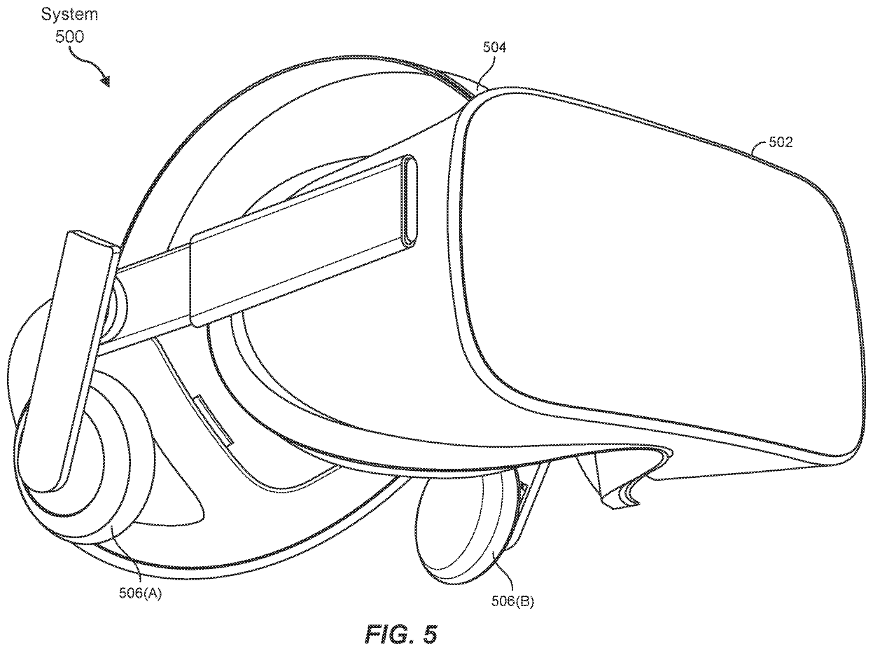

The following will provide, with reference to FIGS. 1-5, an overview of the manufacture and characterization of piezoelectric polymers having high polydispersity and high modulus, as well as concepts for incorporating such polymers into optical systems. The discussion associated with FIGS. 1-3 relates to example manufacturing paradigms for producing high strength and high modulus piezoelectric polyvinylidene fluoride thin films and fibers suitable for a variety of optical, mechanical, and optomechanical applications. The discussion associated with FIGS. 4 and 5 relates to exemplary virtual reality and augmented reality devices that may include one or more piezoelectric polymer thin films.

In conjunction with various embodiments, a polymer thin film may be described with reference to three mutually orthogonal axes that are aligned with the machine direction (MD), the transverse direction (TD), and the normal direction (ND) of a thin film orientation system, and which may correspond respectively to the length, width, and thickness dimensions of the polymer thin film. Throughout various embodiments and examples of the instant disclosure, the machine direction may correspond to the y-direction of a polymer thin film, the transverse direction may correspond to the x-direction of the polymer thin film, and the normal direction may correspond to the z-direction of the polymer thin film.

A single stage thin film orientation system for forming a piezoelectric polymer thin film is shown schematically in FIG. 1. System 100 may include a thin film input zone 130 for receiving and pre-heating a crystallizable portion 110 of a polymer thin film 105, a thin film output zone 138 for outputting a crystallized and oriented portion 115 of the polymer thin film 105, and a clip array 120 extending between the input zone 130 and the output zone 138 that is configured to grip and guide the polymer thin film 105 through the system 100, i.e., from the input zone 130 to the output zone 138. Clip array 120 may include a plurality of movable first clips 124 that are slidably disposed on a first track 125 and a plurality of movable second clips 126 that are slidably disposed on a second track 127.

Polymer thin film 105 may include a single polymer layer or multiple (e.g., alternating) layers of first and second polymers, such as a multilayer ABAB . . . structure. Alternately, polymer thin film 105 may include a composite architecture having a crystallizable polymer thin film and a high Poisson's ratio polymer thin film directly overlying the crystallizable polymer thin film (not separately shown). In some embodiments, a polymer thin film composite may include a high Poisson's ratio polymer thin film reversibly laminated to, or printed on, a single crystallizable polymer thin film or a multilayer polymer thin film.

During operation, proximate to input zone 130, clips 124, 126 may be affixed to respective edge portions of polymer thin film 105, where adjacent clips located on a given track 125, 127 may be disposed at an inter-clip spacing 151, 152, respectively. For simplicity, in the illustrated view, the inter-clip spacing 151 along the first track 125 within input zone 130 may be equivalent or substantially equivalent to the inter-clip spacing 152 along the second track 127 within input zone 130. As will be appreciated, in alternate embodiments, within input zone 130, the inter-clip spacing 151 along the first track 125 may be different than the inter-clip spacing 152 along the second track 127.

In addition to input zone 130 and output zone 138, system 100 may include one or more additional zones 132, 134, 136, etc., where each of: (i) the translation rate of the polymer thin film 105, (ii) the shape of first and second tracks 125, 127, (iii) the spacing between first and second tracks 125, 127, (iv) the inter-clip spacing 151-156, and (v) the local temperature of the polymer thin film 105, etc. may be independently controlled.

In an example process, as it is guided through system 100 by clips 124, 126, polymer thin film 105 may be heated to a selected temperature within each of zones 130, 132, 134, 136, 138. Fewer or a greater number of thermally controlled zones may be used. As illustrated, within zone 132, first and second tracks 125, 127 may diverge along a transverse direction such that polymer thin film 105 may be stretched in the transverse direction while being heated, for example, to a temperature greater than its glass transition temperature (T_{g}) but less than the onset of melting. In some embodiments, a transverse stretch ratio (strain in the transverse direction/strain in the machine direction) may be approximately 10 or greater, e.g., 10, 15, 20, 25, or 30, including ranges between any of the foregoing values.

In accordance with certain embodiments, a polymer thin film may be stretched by a factor of 10 or more without fracture due at least in part to the high molecular weight of its component(s). In particular, high molecular weight polymers allow the thin film to be stretched at higher temperatures, which may decrease chain entanglement and produce a desirable combination of higher modulus, high transparency, and low haze in the stretched thin film.

Referring still to FIG. 1, within zone 132 the spacing 153 between adjacent first clips 124 on first track 125 and the spacing 154 between adjacent second clips 126 on second track 127 may decrease relative to the respective inter-clip spacing 151, 153 within input zone 130. In certain embodiments, the decrease in clip spacing 153, 154 from the initial spacings 151, 152 may scale approximately as the square root of the transverse stretch ratio. The actual ratio may depend on the Poisson's ratio of the polymer thin film as well as the requirements for the stretched thin film, including flatness, thickness, etc. Accordingly, in some embodiments, the in-plane axis of the polymer thin films that is perpendicular to the stretch direction may relax by an amount equal to the square root of the stretch ratio in the stretch direction. By decreasing the clip spacings 153, 154 relative to inter-clip spacings 151, 152, the polymer thin film may be allowed to relax along the machine direction while being stretched along the transverse direction.

A temperature of the polymer thin film may be controlled within each heating zone. Withing stretching zone 132, for example, a temperature of the polymer thin film 105 may be constant or independently controlled within sub-zones 165, 170, for example. In some embodiments, the temperature of the polymer thin film 105 may be decreased as the stretched polymer thin film 105 enters zone 134. Rapidly decreasing the temperature (i.e., thermal quenching) following the act of stretching within zone 132 may enhance the conformability of the polymer thin film 105. In some embodiments, the polymer thin film 105 may be thermally stabilized, where the temperature of the polymer thin film 105 may be controlled within each of the post-stretch zones 134, 136, 138. A temperature of the polymer thin film may be controlled by forced thermal convection or by radiation, for example, IR radiation, or a combination thereof.

Downstream of stretching zone 132, according to some embodiments, a transverse distance between first track 125 and second track 127 may remain constant or, as illustrated, initially decrease (e.g., within zone 134 and zone 136) prior to assuming a constant separation distance (e.g., within output zone 138). In a related vein, the inter-clip spacing downstream of stretching zone 132 may increase or decrease relative to inter-clip spacing 153 along first track 125 and inter-clip spacing 154 along second track 127. For example, inter-clip spacing 155 along first track 125 within output zone 138 may be less than inter-clip spacing 153 within stretching zone 132, and inter-clip spacing 156 along second track 127 within output zone 138 may be less than inter-clip spacing 154 within stretching zone 132. According to some embodiments, the spacing between the clips may be controlled by modifying the local velocity of the clips on a linear stepper motor line, or by using an attachment and variable clip-spacing mechanism connecting the clips to the corresponding track.

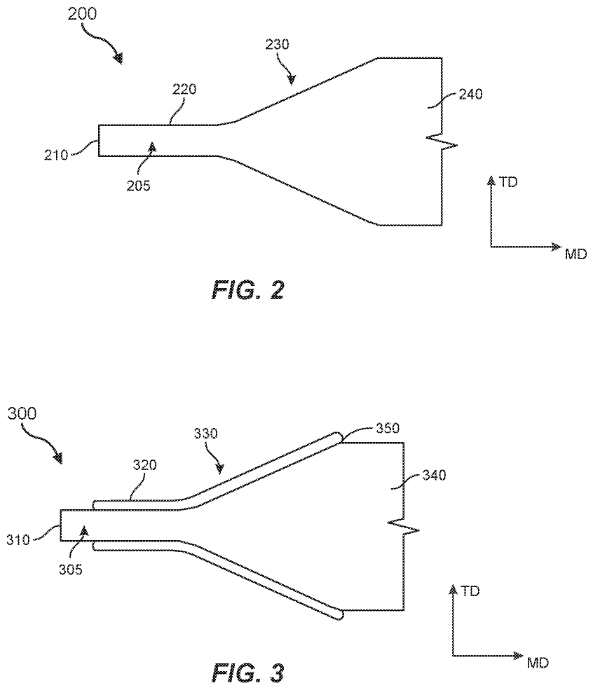

A further example thin film orientation method is depicted schematically in FIG. 2. In method 200, a polymer thin film 205 may include a crystallizable portion 210 that is heated within heating zone 220 and stretched within stretching zone 230 prior to exiting the method as an oriented polymer thin film 240. In the illustrated example, polymer thin film 205 may be stretched along the transverse direction (TD) to a final width that is approximately 5.5× an initial width.

During the act of stretching, the polymer thin film 205 may relax along the machine direction (MD). For instance, the polymer thin film 205 may relax along the machine direction by at least approximately 10% of the Poisson's ratio of the polymer, e.g., 10, 20, 30, 40, 50, 60, 70, 80, 90, 95, or 99% of the Poisson's ratio of the polymer thin film, including ranges between any of the foregoing values.

An alternate method and apparatus for stretching and orienting a polymer thin film is shown in FIG. 3. In method 300, a polymer thin film 305 having a crystallizable portion 310 enters a thin film orientation apparatus 330 and is affixed to guide elements 320 using mechanical or chemical means, such as clips or a reversible adhesive system (not shown). The polymer thin film 305 may be heated and then stretched along the transverse direction as guides 320 diverge. During the act of stretching, the geometry of thin film orientation apparatus 330 may locally decrease the translation rate along the machine direction, which may allow an attendant relaxation of the polymer thin film (i.e., along the machine direction). The polymer thin film may be separated from the guide elements 330 withing region 350 to form a stretched and orientated polymer thin film 340.

Disclosed are piezoelectric polymers and methods of manufacturing piezoelectric polymers, e.g., thin films and fibers, that exhibit an elevated modulus along at least one direction and accordingly an attendant enhancement in their piezoelectric response. The piezoelectric response may be improved by pre-stretching the polymer material to a very high stretch ratio, which may unfold elastic lamellar polymer crystals and reorient crystallites and/or polymer chains within the polymer matrix.

For many low molecular weight polymers, a requisite degree of stretching typically causes fracture or voiding that compromises optical quality. In addition, chain entanglement and high viscosity characteristic of high molecular weight polymers may limit their processability. Moreover, high stretch ratios may limit the maximum achievable thickness in stretched thin films and fibers. In accordance with various embodiments, Applicants have shown that high modulus thin films and fibers may be produced from a polydisperse mixture of suitable ultrahigh or high molecular weight materials (MW>350 Daltons) and medium, low, or very low molecular weight miscible polymers, oligomers, or curable monomers (MW<300 Daltons).

The ratio of the ultrahigh and high MW component(s) to the medium to very low MW component(s) in example polymer systems may range from approximately 70:30 to approximately 99:1. In contrast to comparative polymer compositions, a stretch ratio greater than 10 may be achieved. Furthermore, stretching may be performed at higher temperatures, optionally in conjunction with exposure to actinic radiation, which may decrease the propensity for chain entanglement and enable the formation of thin films and fibers having a high modulus without inducing substantial opacity or haze. Example polymers may include PVDF and its copolymers such as PVDF-TrFE.

### EXAMPLE EMBODIMENTS

Example 1: A piezoelectric polymer article having a Young's modulus of at least approximately 5 GPa along at least one dimension of the polymer article.

Example 2: The piezoelectric polymer article according to Example 1, where the Young's modulus of the polymer article is at least approximately 5 GPa along each of a pair of mutually orthogonal in-plane axes of the polymer article.

Example 3: The piezoelectric polymer article according to any of Examples 1 and 2, where the piezoelectric polymer includes polyvinylidene fluoride.

Example 4: The piezoelectric polymer article according to any of Examples 1-3 where the piezoelectric polymer is characterized by a polydispersity index of at least approximately 2.

Example 5: The piezoelectric polymer article according to any of Examples 1-4, where the polymer article includes a thin film.

Example 6: The piezoelectric polymer article according to any of Examples 1-5, where the polymer article includes a thin film having a uniaxial orientation that is characterized by a stretch ratio of at least approximately 400%.

Example 7: The piezoelectric polymer article according to any of Examples 1-6, where the polymer article includes a thin film having a biaxial orientation that is characterized by a stretch ratio along each orientation of at least approximately 400%.

Example 8: The piezoelectric polymer article according to any of Examples 1-7, where a piezoelectric coefficient of the polymer article is at least approximately 20 pC/N along at least one dimension of the polymer article.

Example 9: The piezoelectric polymer article according to any of Examples 1-8, where the polymer article is characterized by at least approximately 80% transparency at 550 nm and less than approximately 10% bulk haze.

Example 10: A piezoelectric polymer article having a polydispersity index of at least approximately 2 and a Young's modulus of at least approximately 5 GPa.

Example 11: The piezoelectric polymer article according to Example 10, where a piezoelectric coefficient of the polymer article is at least approximately 20 pC/N along at least one dimension of the polymer article.

Example 12: A method includes applying a tensile stress to a polymer thin film along at least one direction and in an amount effective to induce at least approximately 500% strain in the polymer thin film and form a piezoelectric polymer article, where the polymer thin film includes less than approximately 10 wt. % liquid solvent.

Example 13: The method of Example 12, where the polymer thin film includes a mixture of a high molecular weight polymer and one or more of a low molecular weight polymer and an oligomer.

Example 14: The method according to any of Examples 12 and 13, where the polymer thin film includes polyvinylidene fluoride.

Example 15: The method according to any of Examples 12-14, where a composition of the polymer thin film is characterized by a polydispersity index of at least approximately 2.

Example 16: The method according to any of Examples 12-15, where a composition of the polymer thin film is characterized by a bimodal molecular weight distribution.

Example 17: The method according to any of Examples 12-16, further including applying an electric field across a thickness dimension of the polymer thin film while applying the tensile stress.

Example 18: The method according to any of Examples 12-17, further including applying an electric field of at least approximately 50 V/micrometer across a thickness dimension of the polymer thin film.

Example 19: The method according to any of Examples 12-18, further including irradiating the polymer thin film with actinic radiation.

Example 20: The method according to any of Examples 12-19, further including irradiating the polymer thin film with actinic radiation within at least one period selected from (a) prior to the stretching, (b) during the stretching, and (c) following the stretching.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 400 in FIG. 4) or that visually immerses a user in an artificial reality (such as, e.g., virtual-reality system 500 in FIG. 5). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 4, augmented-reality system 400 may include an eyewear device 402 with a frame 410 configured to hold a left display device 415(A) and a right display device 415(B) in front of a user's eyes. Display devices 415(A) and 415(B) may act together or independently to present an image or series of images to a user. While augmented-reality system 400 includes two displays, embodiments of this disclosure may be implemented in augmented-reality systems with a single NED or more than two NEDs.

In some embodiments, augmented-reality system 400 may include one or more sensors, such as sensor 440. Sensor 440 may generate measurement signals in response to motion of augmented-reality system 400 and may be located on substantially any portion of frame 410. Sensor 440 may represent one or more of a variety of different sensing mechanisms, such as a position sensor, an inertial measurement unit (IMU), a depth camera assembly, a structured light emitter and/or detector, or any combination thereof. In some embodiments, augmented-reality system 400 may or may not include sensor 440 or may include more than one sensor. In embodiments in which sensor 440 includes an IMU, the IMU may generate calibration data based on measurement signals from sensor 440. Examples of sensor 440 may include, without limitation, accelerometers, gyroscopes, magnetometers, other suitable types of sensors that detect motion, sensors used for error correction of the IMU, or some combination thereof.

In some examples, augmented-reality system 400 may also include a microphone array with a plurality of acoustic transducers 420(A)-420(J), referred to collectively as acoustic transducers 420. Acoustic transducers 420 may represent transducers that detect air pressure variations induced by sound waves. Each acoustic transducer 420 may be configured to detect sound and convert the detected sound into an electronic format (e.g., an analog or digital format). The microphone array in FIG. 4 may include, for example, ten acoustic transducers: 420(A) and 420(B), which may be designed to be placed inside a corresponding ear of the user, acoustic transducers 420(C), 420(D), 420(E), 420(F), 420(G), and 420(H), which may be positioned at various locations on frame 410, and/or acoustic transducers 420(1) and 420(J), which may be positioned on a corresponding neckband 405.

In some embodiments, one or more of acoustic transducers 420(A)-(J) may be used as output transducers (e.g., speakers). For example, acoustic transducers 420(A) and/or 420(B) may be earbuds or any other suitable type of headphone or speaker.

The configuration of acoustic transducers 420 of the microphone array may vary. While augmented-reality system 400 is shown in FIG. 4 as having ten acoustic transducers 420, the number of acoustic transducers 420 may be greater or less than ten. In some embodiments, using higher numbers of acoustic transducers 420 may increase the amount of audio information collected and/or the sensitivity and accuracy of the audio information. In contrast, using a lower number of acoustic transducers 420 may decrease the computing power required by an associated controller 450 to process the collected audio information. In addition, the position of each acoustic transducer 420 of the microphone array may vary. For example, the position of an acoustic transducer 420 may include a defined position on the user, a defined coordinate on frame 410, an orientation associated with each acoustic transducer 420, or some combination thereof.

Acoustic transducers 420(A) and 420(B) may be positioned on different parts of the user's ear, such as behind the pinna, behind the tragus, and/or within the auricle or fossa. Or, there may be additional acoustic transducers 420 on or surrounding the ear in addition to acoustic transducers 420 inside the ear canal. Having an acoustic transducer 420 positioned next to an ear canal of a user may enable the microphone array to collect information on how sounds arrive at the ear canal. By positioning at least two of acoustic transducers 420 on either side of a user's head (e.g., as binaural microphones), augmented-reality device 400 may simulate binaural hearing and capture a 3D stereo sound field around about a user's head. In some embodiments, acoustic transducers 420(A) and 420(B) may be connected to augmented-reality system 400 via a wired connection 430, and in other embodiments acoustic transducers 420(A) and 420(B) may be connected to augmented-reality system 400 via a wireless connection (e.g., a BLUETOOTH connection). In still other embodiments, acoustic transducers 420(A) and 420(B) may not be used at all in conjunction with augmented-reality system 400.

Acoustic transducers 420 on frame 410 may be positioned in a variety of different ways, including along the length of the temples, across the bridge, above or below display devices 415(A) and 415(B), or some combination thereof. Acoustic transducers 420 may also be oriented such that the microphone array is able to detect sounds in a wide range of directions surrounding the user wearing the augmented-reality system 400. In some embodiments, an optimization process may be performed during manufacturing of augmented-reality system 400 to determine relative positioning of each acoustic transducer 420 in the microphone array.

In some examples, augmented-reality system 400 may include or be connected to an external device (e.g., a paired device), such as neckband 405. Neckband 405 generally represents any type or form of paired device. Thus, the following discussion of neckband 405 may also apply to various other paired devices, such as charging cases, smart watches, smart phones, wrist bands, other wearable devices, hand-held controllers, tablet computers, laptop computers, other external compute devices, etc.

As shown, neckband 405 may be coupled to eyewear device 402 via one or more connectors. The connectors may be wired or wireless and may include electrical and/or non-electrical (e.g., structural) components. In some cases, eyewear device 402 and neckband 405 may operate independently without any wired or wireless connection between them. While FIG. 4 illustrates the components of eyewear device 402 and neckband 405 in example locations on eyewear device 402 and neckband 405, the components may be located elsewhere and/or distributed differently on eyewear device 402 and/or neckband 405. In some embodiments, the components of eyewear device 402 and neckband 405 may be located on one or more additional peripheral devices paired with eyewear device 402, neckband 405, or some combination thereof.

Pairing external devices, such as neckband 405, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 400 may be provided by a paired device or shared between a paired device and an eyewear device, thus reducing the weight, heat profile, and form factor of the eyewear device overall while still retaining desired functionality. For example, neckband 405 may allow components that would otherwise be included on an eyewear device to be included in neckband 405 since users may tolerate a heavier weight load on their shoulders than they would tolerate on their heads. Neckband 405 may also have a larger surface area over which to diffuse and disperse heat to the ambient environment. Thus, neckband 405 may allow for greater battery and computation capacity than might otherwise have been possible on a stand-alone eyewear device. Since weight carried in neckband 405 may be less invasive to a user than weight carried in eyewear device 402, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 405 may be communicatively coupled with eyewear device 402 and/or to other devices. These other devices may provide certain functions (e.g., tracking, localizing, depth mapping, processing, storage, etc.) to augmented-reality system 400. In the embodiment of FIG. 4, neckband 405 may include two acoustic transducers (e.g., 420(1) and 420(J)) that are part of the microphone array (or potentially form their own microphone subarray). Neckband 405 may also include a controller 425 and a power source 435.

Acoustic transducers 420(1) and 420(J) of neckband 405 may be configured to detect sound and convert the detected sound into an electronic format (analog or digital). In the embodiment of FIG. 4, acoustic transducers 420(1) and 420(J) may be positioned on neckband 405, thereby increasing the distance between the neckband acoustic transducers 420(1) and 420(J) and other acoustic transducers 420 positioned on eyewear device 402. In some cases, increasing the distance between acoustic transducers 420 of the microphone array may improve the accuracy of beamforming performed via the microphone array. For example, if a sound is detected by acoustic transducers 420(C) and 420(D) and the distance between acoustic transducers 420(C) and 420(D) is greater than, e.g., the distance between acoustic transducers 420(D) and 420(E), the determined source location of the detected sound may be more accurate than if the sound had been detected by acoustic transducers 420(D) and 420(E).

Controller 425 of neckband 405 may process information generated by the sensors on neckband 405 and/or augmented-reality system 400. For example, controller 425 may process information from the microphone array that describes sounds detected by the microphone array. For each detected sound, controller 425 may perform a direction-of-arrival (DOA) estimation to estimate a direction from which the detected sound arrived at the microphone array. As the microphone array detects sounds, controller 425 may populate an audio data set with the information. In embodiments in which augmented-reality system 400 includes an inertial measurement unit, controller 425 may compute all inertial and spatial calculations from the IMU located on eyewear device 402. A connector may convey information between augmented-reality system 400 and neckband 405 and between augmented-reality system 400 and controller 425. The information may be in the form of optical data, electrical data, wireless data, or any other transmittable data form. Moving the processing of information generated by augmented-reality system 400 to neckband 405 may reduce weight and heat in eyewear device 402, making it more comfortable to the user.

Power source 435 in neckband 405 may provide power to eyewear device 402 and/or to neckband 405. Power source 435 may include, without limitation, lithium ion batteries, lithium-polymer batteries, primary lithium batteries, alkaline batteries, or any other form of power storage. In some cases, power source 435 may be a wired power source. Including power source 435 on neckband 405 instead of on eyewear device 402 may help better distribute the weight and heat generated by power source 435.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 500 in FIG. 5, that mostly or completely covers a user's field of view. Virtual-reality system 500 may include a front rigid body 502 and a band 504 shaped to fit around a user's head. Virtual-reality system 500 may also include output audio transducers 506(A) and 506(B). Furthermore, while not shown in FIG. 5, front rigid body 502 may include one or more electronic elements, including one or more electronic displays, one or more inertial measurement units (IMUS), one or more tracking emitters or detectors, and/or any other suitable device or system for creating an artificial-reality experience.

Artificial-reality systems may include a variety of types of visual feedback mechanisms. For example, display devices in augmented-reality system 400 and/or virtual-reality system 500 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 400 and/or virtual-reality system 500 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 400 and/or virtual-reality system 500 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and may be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

As used herein, the term “substantially” in reference to a given parameter, property, or condition may mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition may be at least approximately 90% met, at least approximately 95% met, or even at least approximately 99% met.

As used herein, the term “approximately” in reference to a particular numeric value or range of values may, in certain embodiments, mean and include the stated value as well as all values within 10% of the stated value. Thus, by way of example, reference to the numeric value “50” as “approximately 50” may, in certain embodiments, include values equal to 50±5, i.e., values within the range 45 to 55.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a polymer thin film that comprises or includes polyvinylidene fluoride include embodiments where a polymer thin film consists essentially of polyvinylidene fluoride and embodiments where a polymer thin film consists of polyvinylidene fluoride.

What is claimed is:

1. A piezoelectric polymer article having a Young's modulus of at least approximately 5 GPa along at least one dimension of the polymer article.

2. The piezoelectric polymer article of claim 1, wherein the Young's modulus of the polymer article is at least approximately 5 GPa along each of a pair of mutually orthogonal in-plane axes of the polymer article.

3. The piezoelectric polymer article of claim 1, wherein the piezoelectric polymer comprises polyvinylidene fluoride.

4. The piezoelectric polymer article of claim 1, wherein the piezoelectric polymer is characterized by a polydispersity index of at least approximately 2.

5. The piezoelectric polymer article of claim 1, wherein the polymer article comprises a thin film.

6. The piezoelectric polymer article of claim 1, wherein the polymer article comprises a thin film having a uniaxial orientation that is characterized by a stretch ratio of at least approximately 400%.

7. The piezoelectric polymer article of claim 1, wherein the polymer article comprises a thin film having a biaxial orientation that is characterized by a stretch ratio along each orientation of at least approximately 400%.

8. The piezoelectric polymer article of claim 1, wherein a piezoelectric coefficient of the polymer article is at least approximately 20 pC/N along at least one dimension of the polymer article.

9. The piezoelectric polymer article of claim 1, wherein the polymer article is characterized by at least approximately 80% transparency at 550 nm and less than approximately 10% bulk haze.

10. A piezoelectric polymer article having a polydispersity index of at least approximately 2 and a Young's modulus of at least approximately 5 GPa.

11. The piezoelectric polymer article of claim 10, wherein a piezoelectric coefficient of the polymer article is at least approximately 20 pC/N along at least one dimension of the polymer article.

12. A method comprising:
applying a tensile stress to a polymer thin film along at least one direction and in an amount effective to induce at least approximately 500% strain in the polymer thin film and form a piezoelectric polymer article, wherein the polymer thin film comprises less than approximately 10 wt. % liquid solvent.

13. The method of claim 12, wherein the polymer thin film comprises a mixture of a high molecular weight polymer and one or more of a low molecular weight polymer and an oligomer.

14. The method of claim 12, wherein the polymer thin film comprises polyvinylidene fluoride.

15. The method of claim 12, wherein a composition of the polymer thin film is characterized by a polydispersity index of at least approximately 2.

16. The method of claim 12, wherein a composition of the polymer thin film is characterized by a bimodal molecular weight distribution.

17. The method of claim 12, further comprising applying an electric field across a thickness dimension of the polymer thin film while applying the tensile stress.

18. The method of claim 12, further comprising applying an electric field of at least approximately 50 V/micrometer across a thickness dimension of the polymer thin film.

19. The method of claim 12, further comprising irradiating the polymer thin film with actinic radiation.

20. The method of claim 12, further comprising irradiating the polymer thin film with actinic radiation within at least one period selected from the group consisting of (a) prior to the stretching, (b) during the stretching, and (c) following the stretching.
